(19) United States
(12) Patent Application Publication
(10) Pub. No.: US 2022/0407566 A1
(43) Pub. Date: Dec. 22, 2022

(54) IMPEDANCE MATCHING IN NEAR-FIELD RF COMMUNICATION DEVICES

(71) Applicant: Drayson Technologies (Europe) Limited, London (GB)

(72) Inventors: Victor DIAZ, London (GB); Vitor FREITAS, London (GB); Sebastian LITWINOW, London (GB); Alison LLOYD, London (GB)

(21) Appl. No.: 17/623,335

(22) PCT Filed: Jun. 29, 2020
(86) PCT No.: PCT/GB2020/051572

§ 371 Date: Dec. 28, 2021

(30) Foreign Application Priority Data
Jun. 28, 2019 (GB) 1909374.9

(51) Int. Cl. H04B 5/00; H03H 7/38

(52) U.S. Cl. CPC H04B 5/0081; H04B 5/0037; H03H 7/383

(57) ABSTRACT

The disclosure provides a controller for a device having near field RF communications capabilities. The controller is configured to: tune the impedance of at least one component of an impedance matching circuit to vary an impedance transformation provided by the impedance matching circuit; determine at least one indication of power output from the circuit, each at least one indication corresponding to an impedance transformation; and identify one of a plurality of modes of the circuit as an operating mode, based on the at least one indication, wherein the impedance matching circuit provides a different impedance transformation in each mode.

### TECHNICAL FIELD

The present invention relates to methods and apparatus, and more particularly to devices incorporating near-field RF communications functionality, and more particularly to such devices incorporating power harvesting functionality for powering auxiliary circuits, independent from said near-field RF communications functionality, and more particularly to impedance matching circuits for such devices, and still more particularly to methods and apparatus for controlling such impedance matching circuits.

### BACKGROUND

Near field RF communications enabled devices are becoming increasingly prevalent, and are now in routine use. A variety of near field RF communications enabled devices are available. These include hand-held mobile telephones (cell phones), smart cards, and computer peripherals to name a few.

Smart cards, also known as chip cards, or integrated circuit cards (ICC), are perhaps the most common type of Near field RF communications enabled device. A wide variety of such pocket-sized cards with embedded integrated circuits are in use in a wide variety of applications. The most frequent uses of such cards relate to financial transactions, mass transit systems, and access control. Smart cards are made of plastic, generally polyvinyl chloride, but sometimes polyethylene-terephthalate-based polyesters, acrylonitrile butadiene styrene or polycarbonate. Reusable smart cards may also be made from paper. Such cards often incorporate an integrated circuit, IC, and some source of power such as a near field RF communications interface for powering the IC and providing data communications to and from it.

An IC device, herein called a chip, traditionally consists of a single semiconductor die which has a particular function and which is adapted to interact with other chips and components. For example, a traditional chip might be a microprocessor, a memory controller, or a memory array. IC systems may include two or more chips, as well as other electronic and electrical components, each attached to and interconnected through a mounting system such as a printed circuit board.

Near field RF communication requires an antenna of one near field RF communicator to be present within the alternating magnetic field (H field) generated by the antenna of another near field RF communicator by transmission of an RF signal (for example a 13.56 MegaHertz signal) to enable the magnetic field (H field) of the RF signal to be inductively coupled between the communicators. The RF signal may be modulated to enable communication of control and/or other data. Ranges of up to several centimetres (generally a maximum of 1 metre) are common for near field RF communicators.

Communication of data between NFC communicators may be via an active communication mode in which the NFC communicator transmits or generates an alternating magnetic field modulated with the data to be communicated and the receiving NFC communicator responds by transmitting or generating its own modulated magnetic field, or via a passive communication mode in which one NFC communicator transmits or generates an alternating magnetic field and maintains that field and the responding NFC communicator modulates the magnetic field to which it is inductively coupled with the data to be communicated, for example by modulating the load on the inductive coupling (“load modulation”). Near field RF communicators may be actively powered, that is have an internal or associated power source, or passively powered, that is derive a power supply from a received magnetic field. Generally an RF transceiver will be actively powered while an RF transponder may be passively or actively powered.

Examples of near field RF communicators are defined in various standards for example ISO/IEC 18092 and ISO/IEC 21481 for NFC communicators, and ISO/IEC 14443 and ISO/IEC 15693 for near field RF communicators.

The ability of near field RF communications devices to be passively powered is a significant benefit. Some near field RF communications chips also provide auxiliary power outputs. This can enable power harvested by the near field RF communicator to be used by other circuits. The level of power available from the auxiliary power output of currently available near field RF communicator chips may be insufficient for many purposes.

### SUMMARY

Aspects and examples of the invention are set out in the appended claims, and may aim to provide adaptive impedance matching for devices having near field RF communications functionality, and auxiliary circuits powered by the near field RF communications signal independent from the near field RF communications functionality.

These and other examples of the disclosure aim to address problems which occur in such devices. For example they may aim to provide improved power efficiency by tuning (e.g. changing) an impedance of a matching circuit based on an indication of power harvested from an RF signal. This may enable greater efficiency in power harvesting and may find particular utility in devices which are handheld. As a result, such devices may in normal use experience unpredictable RF field strengths.

The inventors in the present case have appreciated that input impedance seen by the antenna of a near field RF communications device may depend on the coupling between the device and the reader. This coupling may depend primarily upon the distance between device and reader and the reader itself. Due to this, it is not possible to design a single matching that provides a maximum amount of power for all different configurations (different readers/different distances). Embodiments of the disclosure may thus provide an adaptive matching system, which may dynamically tune the input impedance of a near field RF system to the one that fits best the conditions experienced by the antenna. This may enable the impedance transformation provided by the circuit to be changed based on the conditions in which the device is operated.

In an aspect there is provided a controller for a device having near field RF communications capabilities, wherein the controller is configured to:
tune the impedance of at least one component of an impedance matching circuit to vary an impedance transformation provided by the impedance matching circuit;
determine at least one indication of power output from the circuit, each at least one indication corresponding to an impedance transformation; and
identify one of a plurality of modes of the circuit as an operating mode, based on the at least one indication, wherein the impedance matching circuit provides a different impedance transformation in each mode. Thus, the controller may determine a plurality of indications of power output from the impedance matching circuit, each indication corresponding to a corresponding one of a plurality of modes of the impedance matching circuit.

The controller may be configured to keep the impedance matching circuit in the operating mode while the device harvests power from a near field RF communications signal via the impedance matching circuit. The indication of power output may comprise a DC output of an auxiliary rectifier coupled to the impedance matching circuit for rectifying the near field RF communications signal for harvesting the power. The near field RF communications enabled device may comprise a splitter, and the splitter may connect the impedance matching circuit to a near field RF communicator and to the rectifier so that an alternating signal received via the impedance matching circuit is divided between the auxiliary rectifier and the near field RF communicator. The splitters described and/or claimed herein may be configured to divide an alternating RF signal into two parts, each part may comprise the signal information encoded on the alternating RF signal. The division may be uneven—for example more power may be provided in one part of the signal than the other.

Determining an indication of power output may comprise determining at least two indications of power output from the circuit in the same mode, and determining a variation of the at least two indications (such as a difference, deviation, or variance). The controller may then identify the operating mode as the mode with the smallest variation and/or a mode in which the variation is less than a threshold value. The controller may be configured to identify one of the modes as the operating mode only in the event that the indication of power output in that mode is greater than a threshold value.

Identifying one of the plurality of modes as an operating mode may comprise comparing an indication of the power output from the circuit in at least two modes, and identifying one of the modes as the operating mode based on the comparison. For example the mode which provides the highest power may be identified as the operating mode. By these and other methods, an operating mode can be identified which is stable and/or which provides acceptable levels of DC output to support additional functionality. Such additional functionality may be performed by auxiliary circuits (of which the controller may be a part). The auxiliary circuits may comprise biometric sensors (such as fingerprint sensors) and other input devices. It may also comprise data processing functionality such as the digital signal processing associated with processing biometric data (e.g. matching the biometric data to stored data). This may enable the auxiliary functionality to support security and authentication functions which are to be carried out by the device.

Any of the apparatus (e.g. the controllers) described herein may be provided in any device comprising near field RF communications capability, and may find particular utility in pocket sized devices, such as handheld devices—e.g. those able to be held in a single hand. For example, it may be provided in a smartcard. It may also be provided in a device which operates, or has functionality able to operate, solely on electrical power derived from a near field RF communications signal.

The present disclosure may provide smartcards, and smartcard blanks—e.g. a laminar component carrying electronic circuitry for incorporation into a smartcard. The disclosure may also provide methods of manufacturing smartcard blanks and smartcards.

The methods comprise providing a component for incorporation into the body of a smartcard. The component may be laminar—e.g. it may be arranged to provide an internal layer of a smartcard. An inductive coupler (e.g. a near field RF communications antenna) may also be provided and may be incorporated into this component or provided separately. A controller such as any one of those described and/or claimed herein, and/or the impedance matching circuitry described and/or claimed herein may then be provided on the component. These components may be provided as part of a mounting system, provided in the smartcard, for mounting a near field RF communicator, such as a chip into the smartcard blank. Such a mounting system may comprise a dielectric substrate, such as a PCB or similar, carrying a chip assembly seat for seating a near field RF communications chip assembly in the card blank. The antenna, and a substrate carrying the components of the circuitry described and/or claimed herein may be integrated into a smartcard or into a smartcard blank in the process of manufacturing a smartcard. It will thus be appreciated that smartcard circuitry of the present disclosure may be provided in a modular unit, such as a card blank with chip seat, to enable a near field RF communicator to be inserted into the smartcard blank during manufacture.

Accordingly in an aspect there is provided an apparatus comprising: a controller for a device having near field RF communications capabilities such as any one of the controllers described and/or claimed herein, and may also comprise any one of the impedance matching circuits described or claimed herein and being arranged to be controlled by the controller to tune the impedance of at least one component of an impedance matching circuit to vary an impedance transformation provided by the impedance matching circuit. The apparatus may also comprise an inductive coupler for coupling inductively with a radio frequency, RF, H-field to provide an alternating RF voltage to the impedance matching circuit.

The apparatus described herein has been described with reference to near field RF communications functionality which is implemented in a chip. It will be appreciated in the context of the present disclosure that this is relevant to any near field RF communicator, such as one which may be implemented in more than one integrated circuit and/or in which some of the functionality of the near field RF communicator is provided by circuits which are not carried on a chip. It will further be appreciated that the controller and/or circuitry of the present disclosure may be implemented in an integrated circuit, which may comprise the near field RF communication functionality described herein. For example, the near field RF communicator, the circuitry and/or the controller may be implemented in a system on chip.

The inductive coupler may be included but is optional, and the apparatus may merely have input connection(s) to allow it to be connected to such an inductive coupler thereby to obtain the alternating RF signal. In other words—the impedance matching circuits and/or the controllers described and claimed herein may be made and sold separately from other components of the near field RF communications enabled devices in which they are intended to be used.

### BRIEF DESCRIPTION OF DRAWINGS

Embodiments of the disclosure will now be described with reference to the accompanying drawings, in which:

FIG. 1 shows a device having near field RF communications capability;

FIG. 2 shows circuitry comprising an impedance matching circuit for use in a device such as that illustrated in FIG. 1;

FIG. 3 shows another example of circuitry comprising an impedance matching circuit for use in a device such as that illustrated in FIG. 1;

FIG. 4 shows another circuitry comprising an impedance matching circuit for use in a device such as that illustrated in FIG. 1; and

FIG. 5 shows another circuitry comprising an impedance matching circuit for use in a device such as that illustrated in FIG. 1.

In the drawings like reference numerals are used to indicate like elements.

### SPECIFIC DESCRIPTION

Described herein are methods and apparatus for providing adaptive impedance matching in a near field RF communications enabled devices and near field RF communicators. This may enable the device to provide optimal use of available RF power in different environments.

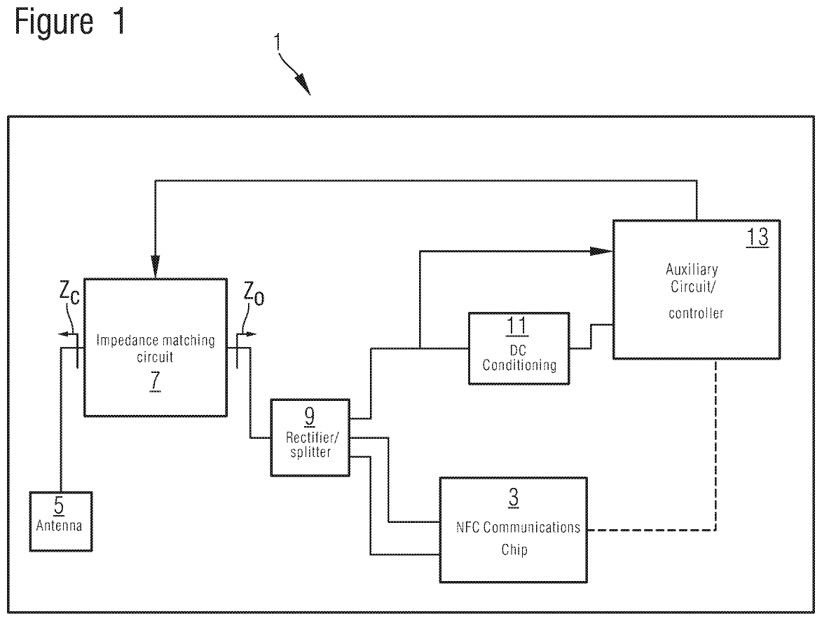

FIG. 1 shows a near field RF communications apparatus 1 comprising a near field radiofrequency (RF) communications chip 3, a near field RF communications antenna 5, an impedance matching circuit 7, a splitting and rectifying circuit 9, a DC conditioning circuit 11, and an auxiliary circuit 13 which may comprise a controller, such as a microprocessor.

The impedance matching circuit 7 connects the antenna 5 to the splitting and rectifying circuit 9. The splitting and rectifying circuit 9 is further connected to the DC conditioning circuit and to the communications chip. The DC conditioning circuit connects a DC output from the splitting and rectifying circuit 9 to the auxiliary circuits.

The near field RF communications antenna 5 comprises an electrical conductor such as a conductive track or wire arranged for coupling inductively with an RF alternating H-field to provide an alternating (e.g. RF) electrical signal. This alternating electrical signal is provided to the impedance matching circuit.

The impedance matching circuit 7 comprises a network of impedances, such as reactive impedances which are preferably capacitors, but which may also be inductors. These impedances are connected together into a network to present an input impedance, Zi, to the antenna, and to present an output impedance, Zo, to the rectifying and splitting circuit 9. At least one impedance of the impedance matching network 7 is arranged to be adjusted by a control signal provided by the controller 13. The alternating electrical signal output from the impedance matching circuit 7 is provided to the rectifying and splitting circuit.

The rectifying and splitting circuit 9 comprises a splitter configured to divide the alternating electrical signal into two parts. It also comprises an auxiliary rectifier arranged to rectify the first part of the signal thereby to provide a rectified signal to the DC conditioning circuit. It is further configured to provide the second part of the alternating electrical signal to the near field RF communicator chip to enable the near field RF communicator chip to perform near field RF communications via the antenna. The auxiliary rectifier of the splitting and rectifying circuitry may be separate from any rectifier provided in the near field RF communicator 3.

The controller 13 is connected for controlling the impedance matching circuit 7, for example by providing a control signal to operate one or more switches for controlling the impedance of the impedance matching circuit 7 (and/or for controlling the impedance of a controllable impedance in that circuit 7, such as a variable capacitor). It may also be connected to obtain an indication of a DC output of the splitting and rectifying circuit 9, for example it may be connected to sense a rectified RF signal, such as that provided from the splitting and rectifying circuit 9 to the DC conditioning circuit 11. This provides one way in which the controller 13 can determine an indication of power output from the circuit.

The controller 13 is configured to change impedance(s) of the impedance matching circuit 7, so that the impedance matching circuit 7 changes between a sequence of different modes of operation, each mode having a different input impedance Zi and/or a different output impedance, Zo. The controller 13 is also configured to determine an indication of the DC output from the splitting and rectifying circuit 9 for each of the modes. Thus, by tuning the impedance of at least one component of the impedance matching circuit 7, the controller is able to vary an impedance transformation provided by the impedance matching circuit 7, and to identify an indication of DC output corresponding to each impedance transformation. By performing this tuning process it is able to determine which of the modes provides the best DC output, and to select an operating mode of the impedance matching circuit 7 on this basis.

This process of course takes a finite time—and it may slow operation of the device. To reduce operating delay, the controller may be configured to perform this tuning process only for a selected period of time. For example, it may begin testing the available modes and then choose the operating mode (from amongst the modes which have been tested) once the selected period of time has elapsed. This may ensure that, whatever criterion is used to identify the operating mode, the tuning process does not interfere with operation of the device as a whole.

The operating mode may be chosen based on one or more of a variety of different criteria, which may be applied using a variety of different approaches. One example is a “time based approach” in which it is assumed that in typical operating there will be a predictable interval of time between the moment that the first power is received until the device (e.g. a smartcard) is in a static position with respect to the near field device with which it is communicating (such as a reader). Thus, in this “time based” approach, the controller may be configured only to perform adjustments to the matching network (tuning) for a fixed period after a near field signal is first received and to cease tuning adopt the best tested mode at the end of that fixed period. Another example is a “power based” approach. For example, if the available modes each provide a stable DC output (e.g. the same level each time they are tested) the device is probably static, so that there is no need to do any more adjustments and the operating mode can simply be chosen by choosing the mode associated with the best DC output from the auxiliary rectifier. This could also work off a minimum power achieved, i.e. once a certain level is (stably) achieved, stop the tuning process. For example, the controller may be configured to control the impedance matching circuit 7 so that an indication of power output is determined at least twice for a mode (perhaps for each of the modes). And, if one of the modes is sufficiently stable (e.g. a variation between two indications of power in that mode is less than a threshold value) then the controller may identify that stable mode as the operating mode of the device. As another example, the controller may be configured to compare the indication of the power output between the different modes, and to select the operating mode based on this comparison. For example, it may select the mode with the highest voltage, highest current, or highest power as the operating mode. As a further example, the controller may be configured to compare the indication of power from the rectifying circuit with a threshold value (such as a minimum power/voltage/current necessary to operate the near field RF chip and/or any auxiliary circuit) and to select an operating mode which provides an indication of power output greater than this threshold value. The controller may be configured to use any combination of the previous examples to determine which one is the most suitable mode of operation. It is worth noting that the tighter the integration between the adaptive matching and the communications processing unit, the better the results are likely to be. It may not be possible to directly integrate the matching with the near field RF communicator as this is often provided by a self-contained chip (e.g. a system on chip, or SoC) while the auxiliary circuit and controller 13 may comprise applications processor provides the applications support (running separately from any low-level processor in the near field RF communicator).

These are just examples of ways in which the controller of the present disclosure may operate, and further examples will become apparent upon consideration of the disclosure which follows.

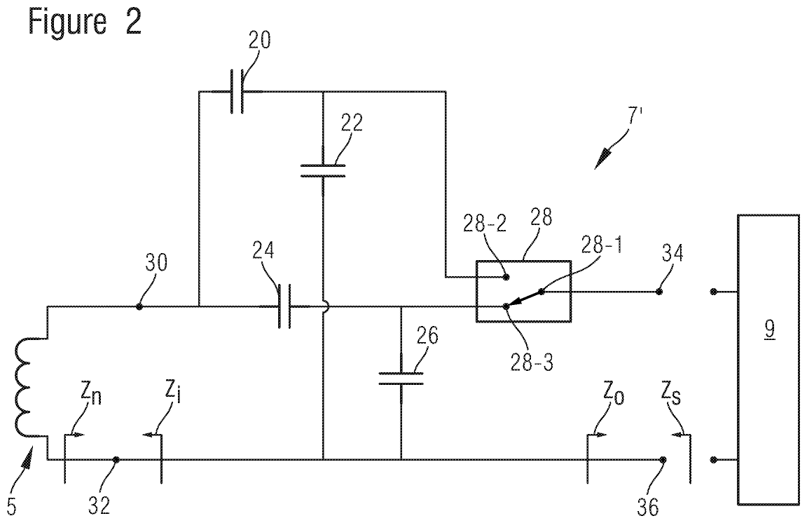

FIG. 2 shows an impedance matching circuit 7′ for use in an apparatus such as that illustrated in FIG. 1. The impedance matching circuit 7′ is configured to provide an impedance transformation between the antenna and the splitting and rectifying circuit 9. The splitting and rectifying circuit 9 may have a fixed impedance Zs, for example approximately 50 Ohms. The antenna may have an impedance Za that is very far from that of the splitter/rectifier, and which may vary depending on the environment in which the apparatus is operating. In order to facilitate maximum power transfer through the impedance matching circuit 7′, the impedance at the input of the impedance matching circuit Zi may be controlled to match (e.g. as closely as possible) that of the antenna Za, and for the impedance at the input of the impedance matching circuit Zo to match (e.g. as closely as possible) that of the splitting and rectifying circuit Zs.

In order to provide this impedance transformation the circuit comprises a plurality of capacitors 20, 22, 24, 26 arranged to provide two different conduction paths through the impedance matching circuit 7′ from its input to its output. The impedance matching circuit 7′ further comprises a switch 28, e.g. a single pole double throw switch. When operated, the switch 28 connects one of these two paths into the circuit, and disconnects the other. The two conduction paths may each have series impedance and/or a parallel impedance. And the series and/or parallel impedance may be different in each path. Thus operation of the switch 28 can favour one of the two paths over the other thereby to change the impedance matching circuit 7′ between two different modes.

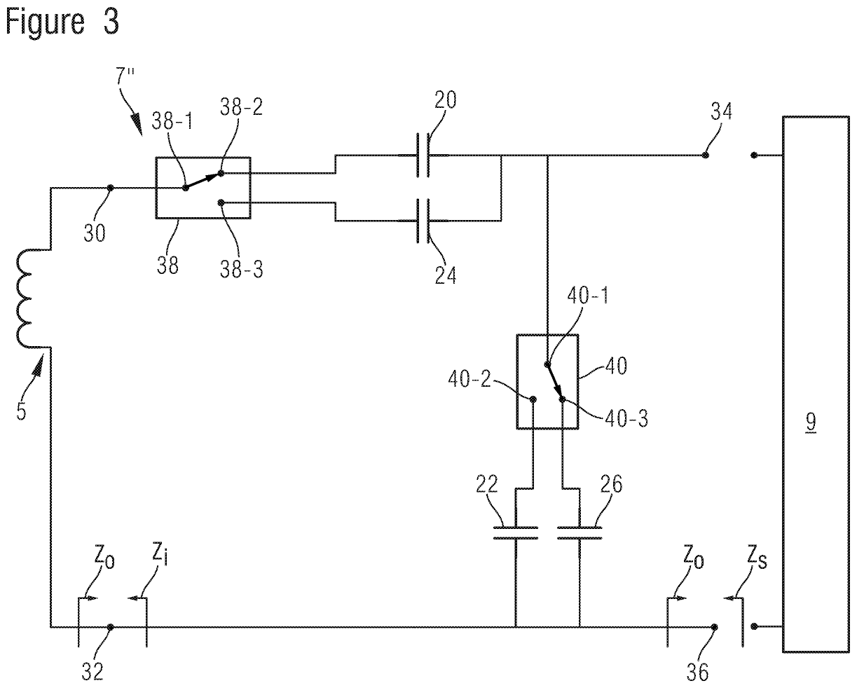

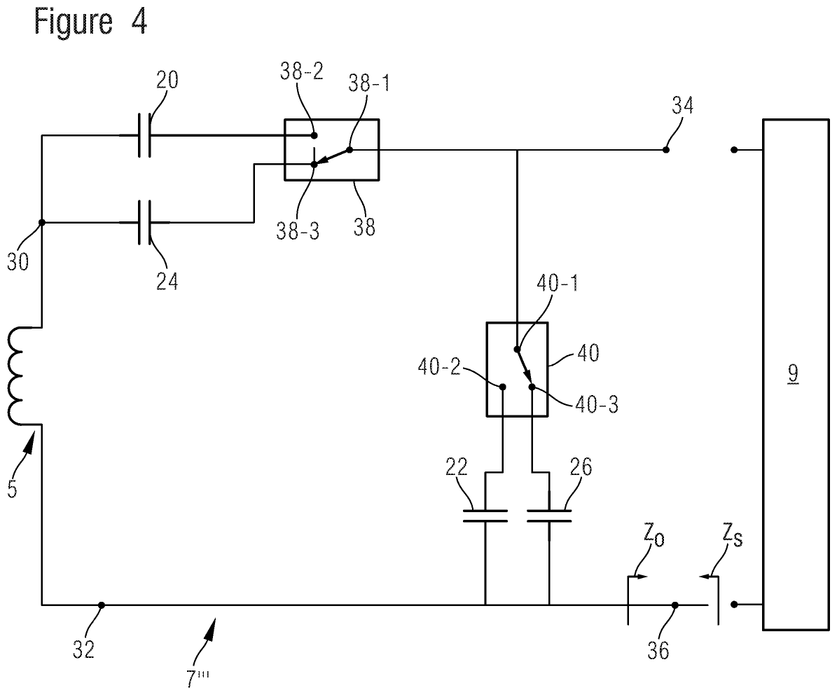

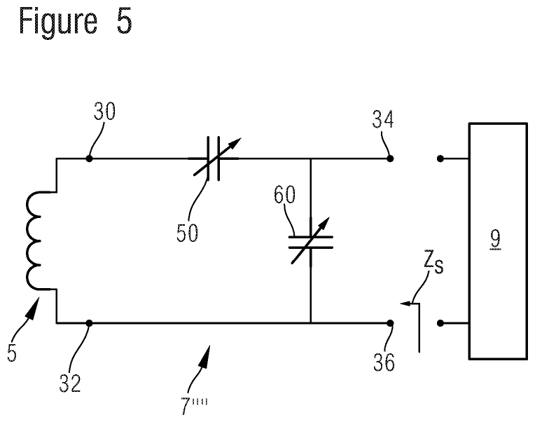

In particular the switch 28 is switchable between a first position, in which the circuit 7′ is in a first mode, and a second position, in which the circuit 7′ is in a second mode. Different ones of the capacitors 20, 22, 24, 26 are connected into the circuit 7 in each of the two modes thereby to provide different impedance Zi, Zo in each mode. Different ways to implement such functionality with a single switch may be provided, and multiple switches may also be used. In some embodiments, switches need not be used, and variable capacitors, such as varactors, may be used instead. One example is illustrated in FIG. 2, and other examples are discussed below with reference to FIG. 3, FIG. 4, and FIG. 5. Any one or more of these arrangements may be used to provide the impedance matching circuit of FIG. 1, and other implementations are possible.

Operation of the apparatus 1 shown in FIG. 1 will now be described, and it will be appreciated that the operations described herein may be carried out with any one or more of the impedance matching circuits described and/or claimed herein.

In operation, the controller 13 controls the impedance matching network 7 to be in a first mode (STATE1). The controller 13 monitors the DC output of the auxiliary rectifier to quantify the output power generated by the auxiliary rectifier with the matching network in this mode (STATE1). The controller 13 then controls the impedance matching network 7 to a second mode (STATE2) by changing one or more impedances of the network 7. The controller continues to monitor the DC output of the auxiliary rectifier to quantify the output power generated by the auxiliary rectifier with the matching network in this mode (STATE2). The controller 13 then compares the indications of power obtained by monitoring the output of the auxiliary rectifier in STATE1 against that obtained in STATE2. The controller 13 then controls the matching network to operate in the mode that provided more power. The matching network 7 is then used in this operating mode while the device performs other functions such as near field RF communications (using the chip 3) and/or auxiliary functionality performed by parts of the device which may be powered by the DC output of the auxiliary rectifier. Thus, to identify an operating mode the controller changes the mode of the impedance matching network 7 through a sequence of available modes for the network 7 and monitors the DC output of the auxiliary rectifier in each mode before comparing the DC output in each of the modes to identify the operating mode as that which provides the desired DC output. This process of identifying an operating mode may be repeated at intervals (e.g. periodically or in response to a trigger condition or control signal).

A variety of refinements of this approach are possible.

For example, the connection between the splitter and the near field RF communicator may comprise an additional switch arranged to be controlled by the controller 13. The controller 13 may be configured to operate the switch to disconnect the near field RF communicator from the splitter prior to performing the process of identifying an operating mode. Once an operating mode has been identified, the controller 13 may operate the additional switch to reconnect the near field RF communicator to the splitter. It may also be configured so that, once the near field RF communicator is reconnected to the splitter it performs the process of re-identifying the operating mode only in one or more of the following circumstances: (i) the DC output of the auxiliary rectifier drops below a minimum threshold level; (ii) a control signal is received from the near field RF communicator (e.g. via the I2C comms, or other digital logic output of the chip). This may enable the near field RF communicator to trigger identification of a new mode for the impedance matching network in the event that communication has ceased, or the available near field RF signal strength is insufficient.

As a second example, the controller 13 may be configured to provide a signal to the near field RF communicator to inhibit the near field RF communicator from performing communications while the controller is identifying an operating mode. The controller and near field RF communicator chip may do this repeatedly, so that periods of identifying an operating mode are interleaved between periods of near filed communication (e.g. synchronised so that they do not take place at the same time. It need not be done repeatedly however, for example it may be that the near field RF communicator does not perform any communication until an operating mode has been identified, and the operating mode then remains unchanged.

The above possibilities may reduce the possibility that the process of identifying an operating mode might impair near field RF communication. Each of the approaches described in the two foregoing examples may be used individually, or in combination. Other possible refinements may also be used.

As a third example, where the apparatus comprises auxiliary circuits which comprise additional functionality in addition to the controller 13, the controller 13 may be inhibited (e.g. prevented) from performing the process of identifying an operating mode during operation of the additional functionality. For example, the controller may be inhibited from performing his process if the power demand of the additional functionality is greater than a threshold level.

As a fourth example, where the apparatus comprises auxiliary circuits which comprise additional functionality in addition to the controller 13, the additional functionality may be inhibited from performing certain operations while the controller is identifying an operating mode. Thus, “power hungry” operations can be delayed until the controller has identified an operating mode for the impedance matching network. In addition, or as an alternative the apparatus may comprise an energy store such as a capacitor arranged to store energy provided from the DC output of the auxiliary rectifier. This energy store may be arranged for powering the additional functionality while the controller is identifying an operating mode for the impedance matching network.

It will be appreciated that “additional functionality” such as that described in the foregoing paragraphs may be implemented by the controller and/or by a component (such as a system on chip SoC) which comprises the controller 13 in addition to the auxiliary circuits.

As noted above—these different approaches may be implemented using any one of a variety of impedance matching networks—and any impedance matching network suitable for use in the relevant near field RF enabled device and having at least one variable impedance may be used. The disclosure which follows explains a number of such examples. Other examples are envisaged as will be appreciated by the skilled addressee in the context of the present disclosure.

FIG. 2 illustrates an impedance matching circuit 7′, and shown in the drawing are also an antenna 5, and a splitting and rectifying circuit 9, such as those described with reference to FIG. 1. The impedance matching circuit 7′ comprises an antenna coupling, having first 30 and second 32 connections for connecting the circuit 7′ to the antenna 5 and for obtaining a signal from the antenna 5. The impedance matching circuit 7′ also comprises a splitter coupling having first 34 and second 36 connections for connecting the impedance matching circuit 7′ to the splitting and rectifying circuit 9, and to provide an alternating electrical signal to the splitting and rectifying circuit 9.

The impedance matching circuit 7′ comprises a switch 28 for switching the impedance matching circuit 7′ between modes. The switch 28 comprises three terminals 28-1, 28-2, 28-3 and is operable in two states. In the first state the first terminal 28-1 is connected to the second terminal 28-2 (and the third terminal 28-3 is disconnected from the first). In the second state the first terminal 28-1 is connected to the third terminal 28-3 (and the second terminal 28-2 is disconnected from the first).

The first terminal 28-1 of the switch is connected to the first connection 34 of the splitter coupling. The impedance matching circuit 7′ comprises a first series capacitor 20 connected in series between a first connection 30 of the antenna coupling and the second terminal 28-2 of the switch. The circuit further comprises a second series capacitor 24 connected in series between the first connection of the antenna coupling and the third terminal 28-3 of the switch.

The impedance matching circuit 7′ further comprises a first parallel capacitor 22 connected between the second terminal of the switch and the second connection of the antenna coupling (please note that, for clarity, the first parallel capacitor is illustrated as being connected to ground, but this ground could be a virtual ground such as one provided by the second connection of the antenna coupling). The circuit also comprises a second parallel capacitor 26 connected between the third terminal 28-3 of the switch and the second connection 32 of the antenna coupling.

The first and second series capacitors may have different capacitances to one another so as to provide a different series impedance in response to operation of the switch 28. The first and second parallel capacitors may have different capacitances to one another so as to provide a different parallel impedance in response to operation of the switch 28. This however is optional and there are circumstances in which the parallel capacitors may be the same as each other, or the series capacitors may be the same as each other, provided that operation of the switch causes a change in the impedance presented by the impedance matching network 7.

An advantage of this approach is that the impedance of the splitting and rectifying circuit Zs may be known a priori, so the impedance of the switch may be chosen simply to match this impedance. For example the impedance of the splitting and rectifying may be designed to be 50 Ohm, in which case a 50 Ohm switch can be used.

FIG. 3 illustrates an alternative impedance matching network 7″, which may have the advantage that the non-selected pathway through the network does not contribute to the impedance presented to the antenna. The arrangement illustrated in FIG. 3 comprises an impedance matching circuit 7″, an antenna, and a splitting and rectifying circuit 9 such as that described with reference to FIG. 1. As with the arrangement illustrated in FIG. 2, the impedance matching circuit 7″ illustrated in FIG. 3 comprises an antenna coupling, having first and second connections. The impedance matching circuit 7″ also comprises a splitter coupling having first and second output connections.

The impedance matching circuit 7″ of FIG. 3 comprises two switches 38, 40, each functionally identical to the switch 28 described above with reference to FIG. 2. In the impedance matching circuit 7″ shown in FIG. 3, the first connection 30 of the antenna coupling is connected to a first terminal 38-1 of a first switch 38. The second terminal 38-2 of the first switch is connected by a first series capacitor 20 to the first connection 34 of the splitter coupling. The third terminal 38-3 of the first switch is connected by a second series capacitor 24 to the first connection 34 of the splitter coupling.

The first terminal 40-1 of the second switch 40 is connected to the first connection 34 of the splitter coupling. The second terminal 40-2 of the second switch 40 is connected by a first parallel capacitor 22 to the second connection 36 of the splitter coupling. The third terminal 40-3 of the second switch 40 is connected by a second parallel capacitor 26 to the second connection 36 of the splitter coupling.

Thus, operating the first switch 38 modifies primarily the series capacitance of the impedance matching network 7″, whereas operating the second switch 40 modifies primarily the parallel impedance of the impedance matching network 7″.

FIG. 4 illustrates an alternative to the arrangement shown in FIG. 3. The impedance matching circuit 7′″ shown in FIG. 3 is identical to that illustrated in FIG. 3 other than in that the arrangement of the first switch 38 is reversed, so that it is separated from the antenna connection by the series capacitors 20, 24 of the network. This may have the advantage of ensuring that the known impedance of the switch can be connected to the known impedance of the splitting and rectifying circuit 9 rather than being exposed to the unpredictable impedance of the antenna.

As illustrated—in FIG. 4, the first series capacitor 20 is connected between the first connection 30 of the antenna coupling and the second terminal 38-2 of the first switch 38. The second series capacitor 24 is connected between the first connection 30 of the antenna coupling and the third terminal 38-3 of the first switch 38. The first terminal 38-1 of the first switch 38 is connected to the first connection 34 of the splitter coupling. The arrangement of the second switch 40 and the parallel capacitors 22, 26 is identical to that described with reference to FIG. 3.

It can thus be seen that the impedance matching network illustrated in FIG. 3 and FIG. 4 have four possible impedance states each providing a different input impedance Zi and/or a different output impedance Zo (e.g. four possible modes).

A greater number of modes can be provided for example by using switches having a greater number of states (e.g. single pole multiple throw switches) with appropriate capacitors connected in series or parallel arrangements between the terminals of those switches and the relevant connection of the splitter coupling (e.g. adding further alternative series and/or parallel capacitors as appropriate).

The series and/or parallel capacitors used in this circuit may each have different impedances from each other. It will also be appreciated that by providing such multi-state switches and a corresponding plurality of paths through the impedance matching network a number of modes may be provided—each having a discrete value of impedance. In these and other embodiments having discrete modes, tuning the impedance of the impedance matching circuit 7′″ may comprise switching between these discrete modes and obtaining an indication of power output in each such mode in order to choose one of the modes as an operating mode.

FIG. 5 illustrates a possible alternative implementation in which, instead of using switches having discrete states to provide a set of discrete impedance modes, variable capacitors 50, 60 are used to provide a continuum of modes. In this configuration, as with the arrangement illustrated in FIG. 2, the impedance matching circuit illustrated in FIG. 5 comprises an antenna coupling, having first and second connections 30, 32. The impedance matching circuit also comprises a splitter coupling having first and second connections 34, 36.

A first variable capacitor 50 is connected between the first connection 30 of the antenna coupling and the first connection 34 of the splitter coupling to provide a variable series capacitance. A second variable capacitor 60 is connected between the first connection 34 of the splitter coupling and the second connection 36 of the splitter coupling to provide a variable parallel capacitance.

The variable capacitors illustrated in FIG. 5, and the switches shown in FIG. 2, FIG. 3, and FIG. 4 may each have control connections (not shown) connected to receive control signals from a controller, such as the controller described with reference to FIG. 1. This can enable the controller to tune the series and/or parallel impedance of the impedance matching network between a plurality of different modes. The controller can then associate, with each mode, an indication of the DC output of an auxiliary rectifier in the splitting and rectifying circuit 9. It can then use these indications to choose an operating mode from amongst the available modes of the impedance matching circuit.

Of course, the arrangement illustrated in FIG. 1 is just one example of an apparatus in which the controllers and impedance matching circuits of the present disclosure may be used. For example, the DC conditioning circuit is optional. As another example, the splitting and rectifying circuit 9 may be provided as a separate splitter with a separate auxiliary rectifier. Examples of suitable splitters are described herein below. As another example, the auxiliary circuit is optional and/or it may consist solely of the controller. The controller has been described as being part of the auxiliary circuit and being separate from the near field RF communications chip but may also be integrated with it and/or provided by suitable configuration of a controller in the near field RF communications chip.

Typically the antenna comprises a loop having one or more turns. It will be appreciated in the context of the present disclosures that an NFC antenna may have a large inductance, perhaps of 1 μH or more. Such antennas may be adapted for coupling with signals in a near field RF frequency band, which generally comprises 13.56 MHz. It will be appreciated in the context of the present disclosure that such signal may have a wavelength of approximately 22 m.

The near field RF communicator chip may comprise an integrated circuit, which may be implemented as a single semiconductor die. This chip may comprise an RF side, and a DC side. The RF side may comprise a front end, for connection to the splitting and rectifying circuit 9. The front end may include things such as a voltage regulator, a dedicated rectifier for the near field RF communicator, or other circuitry for connecting the near field RF communicator to the antenna. The RF side of the chip may also comprise a controller for performing simple data operations such as modulating and demodulating data from signals received via the antenna. The DC side of the chip may comprise a data store such as an EEPROM or other memory, and I²C or SPI interface for performing data communications, and a controller. The DC side of the chip may also comprise cryptographic hardware (e.g. a secure element). The near field RF communicator chip may be configured to be powered by the alternating signal received from the splitting and rectifying circuit 9. The near field RF communicator chip may further be connected to the controller. For example the controller may be connected to the DC side of the chip for performing communication with or via the chip—e.g. to control it and/or to be controlled by it. The controller may also be integrated with the chip.

The splitter described herein may be such as those described in the applicant's co-pending patent applications GB1805310, GB1807396.5, and GB1811880.2, the entirety of which applications is hereby incorporated by reference for all purpose as if fully set forth herein. For example, the splitter may comprise a splitter, for splitting alternating electrical signals, the splitter comprising a network of lumped capacitors comprising: a first stage, MN1, for connection to an antenna coupling and having a first input impedance Z1 and a first output impedance Z1′; a second stage, MN2, connected to the first stage and to an auxiliary power provider, such as an auxiliary rectifier, for providing a first part of the alternating electrical signal to the auxiliary power provider, the second stage having second input impedance Z2′ and a second output impedance Z2; and a third stage, MN3, connected to the first stage and to the chip coupling for providing a second part of the alternating electrical signal to the chip coupling, the second stage having third input impedance Z3′ and a third output impedance Z3; wherein the lumped capacitors have capacitance values selected so that the first output impedance, Z1′, is equal to the complex conjugate of the sum of the second input impedance, Z2′, and the third input impedance, Z3′. Such a splutter network may consist solely of lumped components, such as lumped capacitors. The capacitances of the lumped capacitors may be chosen so that the real part of the first output impedance, Z1′, is greater than or equal to the real part of the first input impedance Z1.

Alternatively, the splitter for splitting alternating electrical signals may comprise: a first port connected to the antenna coupling and having a first input impedance; a second port connected to the first port and configured to provide a first part of the alternating electrical signal to the auxiliary power provider; and a third port connected to the first port and configured to provide a second part of the alternating electrical signal to the near field RF communicator; wherein the splitter is configured to maintain the first input impedance so that: the output impedance of the second port is maintained in the event of fluctuations in the output impedance of the third port; and the output impedance of the third port is maintained in the event of fluctuations in the output impedance of the second port. For example, the splitter may comprise a Wilkinson divider.

The controller of the apparatus described herein may comprise an ADC, and digital logic configured to perform the comparisons and other control operations described herein. Where an ADC is used, a degree of signal averaging and smoothing may be performed in the digital domain and/or by the ADC. It will also be appreciated however that the output of the rectifier may provide some smoothing, and the comparisons described herein could be performed by analogue logic, for example using analogue comparators such as those which can be provided by arrangements of current mirrors. In some examples the functionality of the controller may be provided by a general purpose processor, which may be configured to perform a method according to any one of those described herein. In some examples the controller may comprise digital logic, such as field programmable gate arrays, FPGA, application specific integrated circuits, ASIC, a digital signal processor, DSP, or by any other appropriate hardware. In some examples, one or more memory elements can store data and/or program instructions used to implement the operations described herein. Embodiments of the disclosure provide tangible, non-transitory storage media comprising program instructions operable to program a processor to perform any one or more of the methods described and/or claimed herein and/or to provide data processing apparatus as described and/or claimed herein. The controller may comprise an analogue control circuit which provides at least a part of this control functionality. An embodiment provides an analogue control circuit configured to perform any one or more of the methods described herein.

The apparatus described and claimed herein may be provided as part of a smartcard or smartcard blank. The smart card blank may have dimensions of a credit card such as that defined in ISO/IEC 7810 standard, for example it may be about 85 mm by about 55 mm (for example 85.60 by 53.98 millimetres). As an alternative, it may have an ID-000 form factor, e.g. about 25 mm by 15 mm (0.98 in×0.59 in) commonly used in SIM cards. The smartcard may comprise a body of a dielectric substance such as plastic, e.g. polyvinyl chloride, or a polyethylene-terephthalate-based polyester. It will be appreciated in the context of the present disclosure that the inductive coupler may be provided into the blank as part of the same manufacturing process as the other smartcard circuitry. In some possibilities the inductive coupler is absent to enable it to be incorporated into the blank separately after the circuitry has been manufactured.

It will be appreciated from the discussion above that the embodiments shown in the Figures are merely exemplary, and include features which may be generalised, removed or replaced as described herein and as set out in the claims. With reference to the drawings in general, it will be appreciated that schematic functional block diagrams are used to indicate functionality of systems and apparatus described herein. It will be appreciated however that the functionality need not be divided in this way, and should not be taken to imply any particular structure of hardware other than that described and claimed below. The function of one or more of the elements shown in the drawings may be further subdivided, and/or distributed throughout apparatus of the disclosure. In some embodiments the function of one or more elements shown in the drawings may be integrated into a single functional unit.

The above embodiments are to be understood as illustrative examples. Further embodiments are envisaged. It is to be understood that any feature described in relation to any one embodiment may be used alone, or in combination with other features described, and may also be used in combination with one or more features of any other of the embodiments, or any combination of any other of the embodiments. Furthermore, equivalents and modifications not described above may also be employed without departing from the scope of the invention, which is defined in the accompanying claims.

1. A controller for a device having near field RF communications capabilities, wherein the controller is configured to:
tune the impedance of at least one component of an impedance matching circuit to vary an impedance transformation provided by the impedance matching circuit;
determine at least one indication of power output from the circuit, each at least one indication corresponding to an impedance transformation; and
identify one of a plurality of modes of the circuit as an operating mode, based on the at least one indication, wherein the impedance matching circuit provides a different impedance transformation in each mode.

2. The controller of claim 1 wherein tuning comprises tuning the impedance for a selected period of time, and the controller is configured to identify the operating mode once this period of time has elapsed.

3. The controller of any preceding claim, wherein:
determining an indication of power output comprises determining at least two indications of power output from the circuit in at least one of the modes; and wherein
the controller is configured to identify one of the modes as the operating mode if a variation in the at least two indications of power in that mode is less than a threshold value.

4. The controller of any preceding claim, wherein identifying one of the plurality of modes as an operating mode comprises comparing an indication of the power output from the circuit in at least two modes, and identifying one of the modes as the operating mode based on the comparison.

5. The controller of any preceding claim, wherein the controller is configured to identify one of the modes as the operating mode if the indication of power output in that mode is greater than a threshold value.

6. The controller of any preceding claim, wherein the controller is further configured to cease tuning and identify the operating mode in response to receiving a power demand signal from another component of the device.

7. The controller of any preceding claim wherein the controller is configured to provide a signal to inhibit operation of another component of the device during tuning.

8. The controller of claim 6 or 7 wherein the another component comprises one of:
(a) a near-field RF communicator, such as a chip; and
(b) a second controller implemented in auxiliary circuits of the device.

9. The controller of any preceding claim, wherein the controller is configured to begin tuning in response to the device receiving a near field RF signal from another near field RF communication device.

10. The controller of any preceding claim, wherein the controller is configured to derive power, to power the controller, from a near field RF signal received by the device.

11. The controller of any preceding claim, wherein tuning comprises changing the circuit between a plurality of predetermined modes.

12. The controller of claim 11, wherein tuning comprises operating at least one switch to switch the circuit between a plurality of configurations each corresponding to one of the plurality of predetermined modes.

13. The controller of claim 12, wherein operating the switch comprises connecting a different component into the circuit in each of the plurality of configurations.

14. The controller of any preceding claim, wherein the circuit comprises at least one component having a variable impedance, and wherein tuning comprises varying the variable impedance.

15. The controller of claim 14, wherein the controller is configured to control the variable impedance based on a comparison of the indication of power output in a first mode with the indication of power output in a second mode.

16. The controller of claim 14, wherein the controller is configured to vary the impedance of the component by one of:
a predetermined value; and
a value based on a comparison of at least one of:
the indication of power output in the first mode with the indication of power output in the second mode; and
the impedance of the component with a threshold impedance value.

17. The controller of any preceding claim, wherein tuning comprises changing the mode of the circuit based on the indication of power from the circuit in an initial mode, and a predetermined impedance transformation provided by the circuit in at least one other mode.

18. The controller of any preceding claim, wherein determining an indication of power comprises obtaining DC signals based on the RF output of the impedance matching circuit.

19. The controller of claim 18, wherein determining an indication of power comprises averaging the obtained DC signals.

20. The controller of any preceding claim, wherein the controller is further configured to tune the circuit to the identified operating mode.

21. An apparatus for use in a device having near field RF communications capabilities, the apparatus comprising the controller of any of claims 1 to 20.

22. The apparatus of claim 21 as dependent on claim 18 or 19, wherein the apparatus comprises an auxiliary rectifier connected to the impedance matching circuit; and the controller is configured to obtain the DC signals from the auxiliary rectifier.

23. The apparatus of claim 22 wherein the auxiliary rectifier is connected to the impedance matching circuit by a splitter.

24. The apparatus of claim 23 wherein the splitter is configured to split an alternating electrical signal from the impedance matching circuit between the auxiliary rectifier and a near field RF communicator.

25. A method of controlling a device having near field RF communications capabilities, the method comprising:
tuning the impedance of at least one component of an impedance matching circuit to vary an impedance transformation provided by the impedance matching circuit;
determining at least one indication of power output from the circuit, each at least one indication corresponding to an impedance transformation and
identifying one of a plurality of modes of the circuit as an operating mode, based on the at least one indication, wherein the impedance matching circuit provides a different impedance transformation in each mode.

26. The method of claim 25 wherein tuning comprises tuning the at least one component for a selected period of time, and wherein the method comprises identifying the operating mode once this period of time has elapsed.

27. The method of claim 25 or 26, wherein:
determining an indication of power output comprises determining at least two indications of power output from the circuit in at least one of the modes; and wherein
the method comprises identifying one of the modes as the operating mode if a variation in the at least two indications of power in that mode is less than a threshold value.

28. The method of any preceding claim, wherein: identifying one of the plurality of modes as an operating mode comprises comparing an indication of the power output from the circuit in at least two modes, and identifying one of the modes as the operating mode based on the comparison.

29. The method of any of claims 25 to 28, comprising identifying one of the modes as the operating mode if the indication of power output in that mode is greater than a threshold value.

30. The method of any of claims 25 to 29, the method further comprising ceasing timing and identifying the operating mode in response to a power demand signal from another component of the device.

31. The method of any preceding claims 25 to 30 wherein the method further comprises providing a signal to inhibit operation of another component of the device during tuning.

32. The method of claim 30 or 31 wherein the other component comprises a near-field RF communicator, such as a chip.

33. The method of any of claims 25 to 32, wherein tuning is begun in response to the device receiving a near field RF signal from another near field RF communication device.

34. The method of any of claims 25 to 33, further comprising deriving power, to power the controller, from a near field RF signal received by the device.

35. The method of any of claims 25 to 34, wherein tuning comprises changing the circuit between a plurality of predetermined modes.

36. The method of claim 35, wherein tuning comprises operating at least one switch to switch the circuit between a plurality of configurations each corresponding to one of the plurality of predetermined modes.

37. The method of claim 36, wherein operating the switch comprises connecting a different component into the circuit in each of the plurality of configurations.

38. The method of any of claims 25 to 37, wherein the circuit comprises at least one component having a variable impedance, and wherein tuning comprises varying the impedance of the component.

39. The method of claim 38, wherein comprising varying the impedance of the component based on a comparison of the indication of power output in a first mode with the indication of power output in a second mode.

40. The method of claim 39, comprising varying the impedance of the component by one of:
a predetermined value; and
a value based on a comparison of at least one of:
the indication of power output in the first mode with the indication of power output in the second mode; and
the impedance of the component with a threshold impedance value.

41. The method of any of claims 25 to 40, wherein tuning comprises changing the mode of the circuit based on the indication of power from the circuit in an initial mode, and a predetermined impedance transformation provided by the circuit in at least one other mode.

42. The method of any of claims 25 to 41, wherein determining an indication of power comprises obtaining DC signals based on the RF output of the impedance matching circuit.

43. The method of claim 42, wherein determining an indication of power comprises averaging the obtained DC signals.

44. The method of any of claims 25 to 43, further comprising tuning the circuit to the identified operating mode.
